(19) United States
(12) Patent Application Publication
(10) Pub. No.: US 2025/0126980 A1
(43) Pub. Date: Apr. 17, 2025

(54) DISPLAY PANEL AND DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Wenyu ZENG, Hefei (CN); Xiuyu ZHANG, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/749,643

(22) Filed: Jun. 21, 2024

Related U.S. Application Data
(63) Continuation of application No. PCT/CN2024/083733, filed on Mar. 26, 2024.

(30) Foreign Application Priority Data
Oct. 12, 2023 (CN) 202311317611.4

(51) Int. Cl. H10K 59/122; H10K 59/40

(52) U.S. Cl. CPC H10K 59/122; H10K 59/40

(57) ABSTRACT

The invention provides a display panel and a display device. The display panel includes a substrate, an isolation structure located on the substrate, a plurality of light emitting units and a touch-control electrode layer. A plurality of isolation openings and a plurality of light transmitting openings are formed surrounded by the isolation structure, and the isolation opening and the light transmitting opening are disposed at intervals. The touch-control electrode layer includes a plurality of touch-control electrode blocks, adjacent touch-control electrode blocks of the plurality of touch-control electrode blocks are connected sequentially to form a grid pattern with a plurality of grid holes, each of an orthographic projection, of the isolation opening and an orthographic projection, of each light transmitting opening of the plurality of light transmitting openings at least partially overlaps with an orthographic projection, of grid hole of the plurality of grid holes.

### CROSS-REFERENCE TO RELATED APPLICATIONS

This application is a continuation of International Application No. PCT/CN2024/083733 filed on Mar. 26, 2024, which claims priority to Chinese patent application No. 202311317611.4, filed on Oct. 12, 2023. Both applications are incorporated herein by reference in their entireties.

### TECHNICAL FIELD

The present application relates to the field of display technologies, and in particular, to a display panel and a display device.

### BACKGROUND

The Organic Light Emitting Diode (OLED) is an organic thin-film electroluminescent unit that has generated significant attention due to its simple manufacturing process, low cost, low power consumption, high brightness, wide viewing angle, high contrast and flexible displays. It is widely used in electronic display products.

However, current electronic display products are limited by their structural design, making it difficult to further reduce pixel spacing, which hinders their application in the field of under-screen recognition and the field of touch control.

### SUMMARY

According to a first aspect of the present disclosure, it provides a display panel, the display panel comprises a substrate, an isolation structure located on the substrate, a plurality of light emitting units and a touch-control electrode layer. A plurality of isolation openings and a plurality of light transmitting openings are formed surrounded by the isolation structure, each isolation opening of the plurality of isolation openings is provided to accommodate a light emitting unit, and the isolation opening and the light transmitting opening are disposed at intervals. The touch-control electrode layer is located at a side, away from the substrate, of the isolation structure, the touch-control electrode layer comprises a plurality of touch-control electrode blocks, adjacent touch-control electrode blocks of the plurality of touch-control electrode blocks are connected sequentially to form a grid pattern with a plurality of grid holes, each of an orthographic projection, located on the substrate, of the isolation opening and an orthographic projection, located on the substrate, of each light transmitting opening of the plurality of light transmitting openings at least partially overlaps with an orthographic projection, located on the substrate, of grid hole of the plurality of grid holes of the grid pattern.

In the forgoing solution, the light transmitting openings are provided in the isolated structures, so that this position where the light emitting openings are located may transmit light to facilitate under-screen recognition (such as fingerprint recognition and imaging) or transparent display; and in addition, since the grid hole of the grid pattern of the touch-control electrode layer corresponds to the light transmitting opening, the touch-control electrode blocks of the grid pattern are kept away from the light transmitting opening, so as to prevent the touch-control electrode layer from blocking the light that is emitted to the light transmitting openings, thereby improving the light transmittance in the area where the light transmitting openings are located.

According to a second aspect of the present disclosure, it provides a display panel, the display panel comprises an isolation structure, a plurality of isolation openings and a plurality of light transmitting openings are formed surrounded by the isolation structure, each isolation opening of the plurality of isolation openings is provided to accommodate a light emitting unit, and the isolation opening and the light transmitting opening are disposed at intervals, the plurality of isolation openings are classified into a first type opening, a second type opening and a third opening, a wavelength of emergent light from a light emitting unit defined by the first type opening, a wavelength of emergent light from a light emitting unit defined by the second type opening and a wavelength of emergent light from a light emitting unit defined by the third opening are decreased sequentially, the plurality of isolation openings are arranged in a plurality of rows and a plurality of columns, the first type opening and the third type opening are disposed in a same row of the plurality of rows and in a same column of the plurality of columns, both in a row and in a column where the first type opening is located, the first type opening and the third type opening are disposed alternately, the row where the first type opening is located and the row where the second type opening is located are disposed alternately, and the column where the first type opening is located and the column where the second type opening is located are disposed alternately, and edges of two opposite ends of at least one of the first type opening, the second type opening, and the third type opening are arc-shaped.

According to a third aspect of the present disclosure, it provides a display device, and the display device includes the display panel in the first aspect or the second aspect.

### BRIEF DESCRIPTION OF THE DRAWINGS

FIG. 1 is a schematic diagram of a planar structure of a display panel according to an embodiment of the present disclosure.

FIG. 2 is an enlarged view of S1 area under a design of the display panel according to FIG. 1.

FIG. 3 is a cross-sectional view of the display panel along a line M1-N1 according to FIG. 2.

FIG. 4 is a schematic diagram of a planar structure of touch-control electrode blocks forming a grid pattern of a touch-control electrode layer in the display panel according to FIG. 2.

FIG. 5 is a schematic diagram of a planar structure of touch-control electrode layers in a display panel according to an embodiment of the present disclosure, and a S2 area in FIG. 5 corresponds to the S1 area in FIG. 1.

FIG. 6 is a cross-sectional view of the touch-control electrode layers along a line M2-N2 according to FIG. 5.

FIG. 7 is a schematic diagram of a planar structure of touch-control electrode layers in another display panel according to an embodiment of the present disclosure, and a S3 area in FIG. 7 corresponds to the S1 area in FIG. 1.

FIG. 8 is a cross-sectional view of the touch-control electrode layers along a line M2-N2 according to FIG. 7.

FIG. 9 is an enlarged view of S1 area under another design of the display panel according to FIG. 1.

FIG. 10 is a schematic diagram of a planar structure of touch-control electrode blocks forming a grid pattern of touch-control electrode layers in the display panel according to FIG. 9.

FIG. 11 is a schematic diagram of a planar structure of a pixel arrangement structure in a display panel according to an embodiment of the present disclosure.

FIG. 12 is a schematic diagram of a planar structure of a pixel arrangement structure in another display panel as a contrast.

FIG. 13 is a cross-sectional view of parts of a display panel according to still another embodiment of the present disclosure.

FIG. 14A to FIG. 14F are process diagrams of a method for manufacturing a display panel according to an embodiment of the present disclosure.

### DETAILED DESCRIPTIONS OF THE EMBODIMENTS

In a display product, some functional film layers in the light emitting units (also referred to as light emitting devices) are formed via evaporation, each light emitting unit contains various functional film layers, the materials of some functional film layers that emit different light rays in the light emitting units are different, therefore multiple alignments are required when evaporating these functional film layers using a mask (such as a fine mask), sufficient space between different light emitting units is reserved in order to ensure alignment accuracy, which limits the arrangement density of the light emitting units (also referred to as sub-pixels) limited, making it challenging to further increase the PPI (pixels per inch) of the display panel.

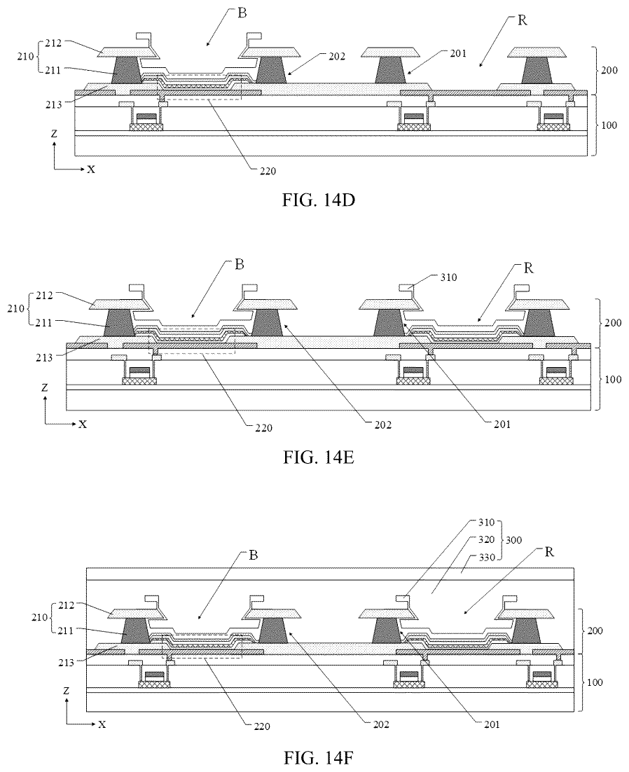

In the present disclosure, an isolation structure is disposed at a gap of the light emitting units to isolate the functional film layers of the adjacent light emitting units, in this way, in a process for evaporating the functional film layers, it is only necessary to perform a full-surface evaporation on the display panel without individually preparing for the functional film layers of each light emitting unit with mask plates, and it is not necessary to consider alignment accuracy during evaporation in this process, so that the size of the gap between light emitting units can be designed to be relatively small to increase PPI (the principle may refer to related descriptions in related embodiments shown in FIG. 14A to FIG. 14F).

However, the disposal of the isolation structure may block the gap between light emitting units and prevent light from going through, so that it is difficult to apply to some scenarios such as under-screen fingerprint recognition and under-screen camera; and in addition, the touch-control function may be considered when the light transmittance of a structure with touch-control function is low in display products, and the structure may block light transmission in the design of display products.

At least one embodiment in the present disclosure provides a display panel to at least solve the above technical problems. The display panel comprises a substrate, an isolation structure located on the substrate, a plurality of light emitting units and a touch-control electrode layer. A plurality of isolation openings and a plurality of light transmitting openings are formed surrounded by the isolation structure. The touch-control electrode layer is located at a side, away from the substrate, of the isolation structure, the touch-control electrode layer comprises a plurality of touch-control electrode blocks, adjacent touch-control electrode blocks of the plurality of touch-control electrode blocks are connected sequentially to form a grid pattern with a plurality of grid holes, each of an orthographic projection, located on the substrate, of the isolation opening and an orthographic projection, located on the substrate, of each light transmitting opening of the plurality of light transmitting openings at least partially overlaps with an orthographic projection, located on the substrate, of grid hole of the plurality of grid holes of the grid pattern. In this way, the light transmitting openings are provided in the isolated structures, so that an area where the light emitting openings are located may transmit light to facilitate under-screen recognition (such as fingerprint recognition, imaging) or transparent display. In addition, since the grid hole of the grid pattern of the touch-control electrode layer corresponds to the light transmitting opening, the touch-control electrode blocks of the grid pattern are kept away from the light transmitting opening, so as to prevent the touch-control electrode layer from blocking the light that emitting to the light transmitting openings, thereby improving the light transmittance of the position where the light transmitting openings are located.

The following may describe a structure of a display panel and a structure of a display device in detail according to at least one embodiment of the present disclosure with reference to the accompanying drawings. In addition, in these accompanying drawings, a spatial rectangular coordinate system is established with a substrate in the display panel as a benchmark, so as to intuitively present a position relationship of each element in the display panel. In the spatial rectangular coordinate system, an X-axis and a Y-axis are parallel to a plane where the substrate is located, and a Z-axis is perpendicular to a plane where the substrate is located.

As shown in FIG. 1 to FIG. 4, a display panel 10 comprises a display area 11 and a frame area surrounding the display area 11, the display area 11 includes a first area 13, and a plurality of sub-pixels (physical structures are light emitting units) such as a R sub-pixel, a G sub-pixel and a B sub-pixel arranged in the display area 11. The first area 13 is configured to have a certain light transmittance for under-screen recognition, imaging or transparent display. It should be noted that some wirings in the framed area 12 may be arranged to the display area 11 in some embodiments of the present disclosure, so that the framed area 12 may be designed as a single-side frame.

The physical structure of the display panel 10 may include a substrate 100, and a display functional layer 200, an isolation structure 210 and a touch-control electrode layer 400 which are disposed on the substrate 100.

The display functional layer 200 is located on the substrate 100 and in the display area 11, and the display functional layer 200 includes a plurality of light emitting units 220, a plurality of isolation openings 201 and a plurality of light transmitting openings 202 are formed surrounded by the isolation structure 210, the isolation opening 201 and the light transmitting opening 202 are disposed at intervals, the light transmitting opening 202 is located in the first area 13, and each isolation opening 201 of the plurality of isolation openings 201 limits a position and is provided to accommodate a light emitting unit 220. It should be noted that “each isolation opening 201 of the plurality of isolation openings 201 is provided to accommodate a light emitting unit 220” may be interpreted as each isolation opening 201 may accommodate all of each light emitting unit 220, or it may be interpreted as each isolation opening 201 may accommodate main part of each light emitting unit 220, and a position for main light emitting area of the light emitting unit 220 is determined by the main part of the light emitting unit 220 (such as a light emitting functional layer mentioned in the following embodiments).

The touch-control electrode layer 400 includes a plurality of touch-control electrode blocks 401, and the touch-control electrode blocks 401 are connected to each other to form a grid pattern with a plurality of grid holes, correspondingly, each grid hole is formed surrounded by the plurality of touch-control electrode blocks 401 connected sequentially, each grid hole corresponds to each isolation opening 201 or each light transmitting opening 202 respectively, and each of an orthographic projection, located on the substrate, of the isolation opening 201 and an orthographic projection, located on the substrate, of each light transmitting opening 202 of the plurality of light transmitting openings 202 at least partially overlaps with an orthographic projection, located on the substrate, of grid hole of the plurality of grid holes of the grid pattern.

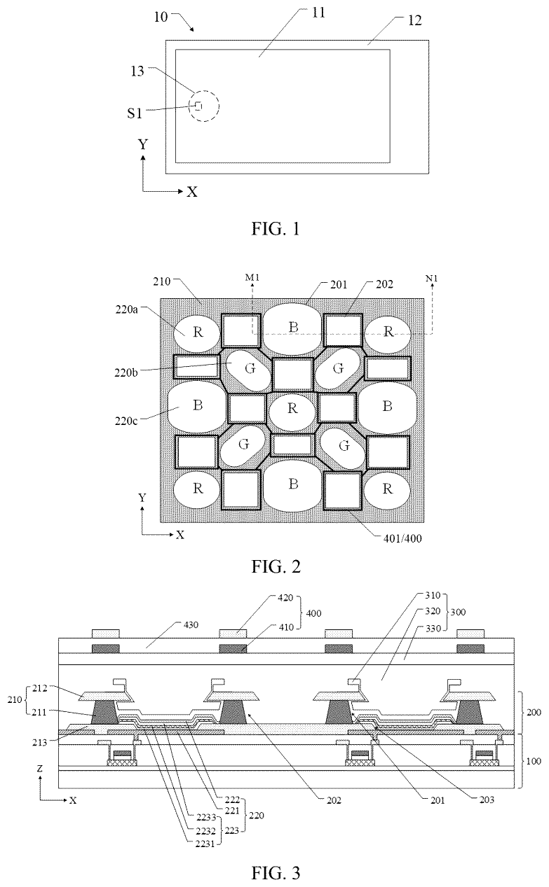

It should be noted that touch-control electrode blocks 401 are equivalent to grid lines for surrounding the grid holes in the grid pattern, and each grid hole may be formed surrounded by at least three touch-control electrode blocks connected to each other. For example, as shown in FIG. 2, there are eight touch-control electrode blocks 401, corresponding to sub-pixel R of the isolation opening 201, for surrounding the grid hole, and there are four touch-control electrode blocks 401, corresponding to the light transmitting opening 202, for surrounding the grid hole. In addition, the grid pattern is formed by a layer of conductive film layer after being patterned, so that there is no physical interface between the touch-control electrode blocks 401 connected to each other.

For example, the conductive material of the touch-control electrode layer 400 may be a metal conductive material, since the conductivity of the metal is high, the voltage drop generated by the touch-control electrode layer 400 in a driving process is relatively small, in addition, the light transmittance of the metal material is low, in the embodiments of the present disclosure, it is necessary to design the grid pattern so that the touch-control electrode layer 400 achieves a relatively higher light transmittance.

For example, the light emitting unit 220 includes an anode 221, a light emitting functional layer 223 and a cathode 222 which are stacked sequentially on the substrate 100, and the light emitting functional layer 223 is located in the isolation opening 201. The light emitting functional layer 223 may include a first common layer 2231, a light emitting layer 2232, and a second common layer 2233, and the first common layer 2231, the light emitting layer 2232, and the second common layer 2233 are sequentially stacked on the anode 221. The first common layer 2231 may include a hole injection layer, a hole transporting layer and an electron-blocking layer. The second common layer 2232 may include an electron injection layer, an electron transporting layer and a hole-blocking layer. The arrangement of the isolation structure 210 needs to make the first common layers 2231 (a major film layer causing current crosstalk) of each light emitting unit 220 electrically disconnected from each other.

For example, the isolation structure 210 may include a support portion 211 and a crown portion 212, the crown portion 212 is located at a side, away from the substrate 100, of the support portion 211, and an orthographic projection, located on the substrate 100, of an end, towards the crown portion 212, of the support portion 211 is located within an orthographic projection, located on the substrate 100, of the crown portion 212. In this way, the arrangement of a part, at least away from the substrate 100, of the isolation structure 210 is to get a shape of wide at the top and narrow at the bottom, so that the isolation structure 210 may block the light emitting functional layer 223 (including the first common layer 2231, and the first common layer 2231 is a main film layer that causes current crosstalk) between adjacent light emitting units to reduce current crosstalk problem between adjacent light emitting units 220.

It should be noted that the support portion 211 and the crown portion 212 may be designed as a structure that are stacked as shown in FIG. 3 in some designs of the present disclosure, and it is convenient to adopt different materials to form the structure, for example, the support portion 211 in the following embodiments is designed to be conductive, but the crown portion 212 is not limited to be conductive material; or in some designs of the present disclosure, the support portion 211 and the crown portion 212 may be configured as an integrated structure to increase the stability of the isolation structure 210.

In at least one embodiment of the present disclosure, as shown in FIG. 3, the support portion 211 may be a conductive structure, the cathode 222 is located in the isolation opening 201, and the cathode 222 is connected to the support portion 211. In this way, the cathodes 222 are in series with the support portion 211 of the isolation structure 210, so that the support portion 211 and the cathode 222 constitute a common electrode for easy driving.

It should be noted that the material of the cathode 222 may be a metal material, the thinner the thickness of the cathode 222, the higher light transmittance of cathode 222, however, resistivity of cathode 222 also increases, if the thickness of the cathode 222 is too thin, under a condition where the isolation structure is not provided, the voltage drop of the cathode 222 (it is the common electrode at the moment) may be too large. In the embodiment of the present disclosure, the cathode 222 is connected with the conductive support portion 211, thus the limitation of the thickness of the cathode 222 may be removed, so that cathode 222 may get a relatively high light transmittance at a smaller thickness.

In at least one embodiment of the present disclosure, the support portion 211 may be a conductive structure, since the conductively of the metal material is high, the voltage drop when the cathode 222 is driven may be reduced. Correspondingly, the metal material can only be transparent when the metal material is extremely thin (on the scale of several tens of nanometers), but the isolation structure 210 needs a certain thickness to separate the light emitting functional layer 223 (the first common layer 2231 included). As a result, it is almost impossible for the support portion 211 in the isolation structure 210 to transmit light, the isolation structure 210 may only be able to transmit light by designing a light transmitting opening 202.

It should be noted that the manufacture method of the isolation structure 210 and the number of the film layers constituting the isolation structure 210 are not limited in the embodiments of the present disclosure, and the design may be tailored according to the specific requirements of the actual process.

For example, in some designs, the isolation structure 210 may be designed as the structure with a shape of wide at the top and narrow at the bottom, that is, the orthographic projection, located on the substrate 100, of the whole support portion 211 is located within the orthographic projection, located on the substrate 100, of the crown portion 212. In one case, the support portion 211 may be designed as an independent film layer, that is, there is no physical interface inside the support portion 211, and each part of the support portion 211 is composed of a same material. For example, in another case, the support portion 211 may be composed of at least two film layers, such as the support portion 211 is composed of two stacked film layers, furthermore, the materials of the two conductive film layers may be molybdenum and aluminum, respectively, and the conductive film layer composed of the molybdenum is located between the substrate and the conductive film layer composed of the aluminum. For example, in this design, the crown portion 212 may be designed to be a non-conductive material film layer (like an inorganic film layer); or the crown portion 212 may be designed to be a conductive film layer, such as the material of the crown portion 212 includes titanium.

For example, in some other designs, the isolation structure 210 may be designed as a structure with a shape of wide at the top and at the bottom and narrow in the middle (similar to a shape of “I”), that is, an orthographic projection, located on the substrate 100, of an end, away from the substrate 100 (top of the isolation structure 210), of the support portion 211 is located within an orthographic projection, located on the substrate 100, of the crown portion 212, and an orthographic projection, located on the substrate 100, of an end, towards the substrate 100 (bottom of the isolation structure 210), of the support portion 211 is located within the orthographic projection, located on the substrate 100, of the crown portion 212. For example, further, the orthographic projection, located on the substrate 100, of the whole support portion 211 is located within the orthographic projection, located on the substrate 100, of the crown portion 212. For example, the support portion 211 may be composed of at least two film layers, such as the support portion 211 is composed of two stacked film layers, furthermore, the materials of the two conductive film layers may be molybdenum and aluminum, respectively, the conductive film layer composed of the molybdenum is located between the substrate and the conductive film layer composed of the aluminum, and the orthographic projection, located on the substrate 100, of the conductive film layer composed of the aluminum is located within the orthographic projection, located on the substrate 100, conductive film layer composed of the molybdenum. For example, in this design, the crown portion 212 may be designed to be a non-conductive material film layer (like an inorganic film layer); or the crown portion 212 may be designed to be a conductive film layer, such as the material of the crown portion 212 is composed of titanium.

In some embodiments of the present disclosure, as shown in FIG. 3, the display panel further includes a pixel-defining layer 213, the pixel-defining layer 213 is located between the isolation structure 210 and the substrate 100, the pixel-defining layer 213 defines a plurality of pixel openings 203 corresponding to the isolation opening 201 respectively to expose the anode 221, an orthographic projection, located on the substrate 100, of the pixel opening 203 is located within an orthographic projection, located on the substrate 100, of the corresponding isolation opening 201, and the pixel-defining layer 213 is located between the isolation structure 210 and the anode 221, an edge of the anode 221 and a gap between the adjacent anodes 221 are covered by the pixel-defining layer 213, so that the anode 221 is exposed by the pixel opening 203. In a scenario where the anode 221 is not in contact with the support portion 211, there may be a relatively large design area, so that the light emitting unit 220 is provided with a relatively large effective area for emitting lights.

In the embodiment of the present disclosure, the specific structure of the touch-control electrode layer is not limited, and the design may be adjusted according to the actual needs of the manufacturing process, In the following, different designs of the touch-control electrode layer are described by different embodiments, and details are as follows.

In the embodiment of the present disclosure, as shown in FIG. 2 to FIG. 6, the touch-control electrode layer 400 includes a plurality of first touch-control electrodes 410 arranged in multiple rows and a plurality of second touch-control electrodes 420 arranged in multiple columns, each first touch-control electrode 410 of the plurality of first touch-control electrodes 410 is composed of a plurality of the touch-control electrode blocks 401 that are interconnected in a row direction (a direction of the X-axis in FIG. 5), and each second touch-control electrode 420 of the plurality of second touch-control electrodes 420 is composed of a plurality of the touch-control electrode blocks 401 that are interconnected in a column direction ((a direction of the Y-axis in FIG. 5), the first touch-control electrode 410 and the second touch-control electrode 420 are spaced apart from each other and intersected with each other to form a touch-control unit, and the grid pattern is formed by the first touch-control electrode 410 and the second touch-control electrode 420.

For example, in some embodiments of the present disclosure, as shown in FIG. 5 and FIG. 6, the first touch-control electrode 410 is located between the second touch-control electrode 420 and the isolation structure 210. Such as a first conductive material layer may be deposited and patterned to form a plurality of first touch-control electrodes 410, and the first conductive material layer is formed to be a plurality of grid holes, so that the plurality of first touch-control electrodes 410 are formed to be a grid pattern; a layer of insulation layer 430 is deposited on the plurality of first touch-control electrodes 410 to cover the plurality of first touch-control electrodes 410; and a second conductive material layer may be deposited on the insulation layer 430 and patterned to form a plurality of second touch-control electrodes 420, and the second conductive material layer is formed to be a plurality of grid holes, so that the plurality of second touch-control electrodes 420 are formed to be the grid pattern. From the point of macroscopic view, an area that each first touch-control electrode 410 of the plurality of the first touch-control electrodes 410 and each second touch-control electrode 420 of the plurality of the second touch-control electrodes 420 intersects and overlaps is an area where the touch-control unit is located, and both the first touch-control electrode 410 and the second touch-control electrode 420 are transparent in the overlapping area.

For example, in the structure shown in FIG. 5 and FIG. 6, an orthographic projection, located on the substrate 100, of the grid holes in the first touch-control electrode 410 overlaps with an orthographic projection, located on the substrate 100, of the grid holes in the second touch-control electrode 420 to improve light transmittance of the touch-control electrode layer 400.

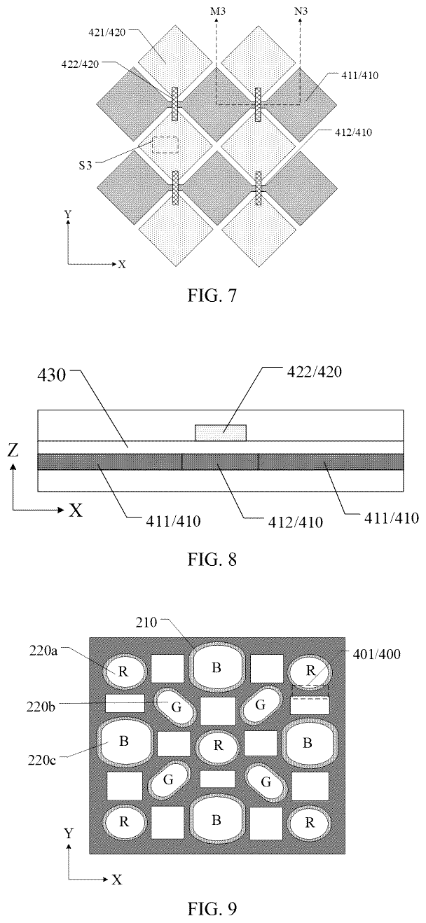

For example, in another embodiments of the present disclosure, as shown in FIG. 7 and FIG. 8, the first touch-control electrode 410 includes a plurality of first sub-touch-control electrodes 411 that are spaced apart from each other and a plurality of first connection parts 412, the second touch-control electrode 420 includes a plurality of second sub-touch-control electrodes 421 that are spaced apart from each other and a plurality of second connection parts 422, for the same first touch-control electrode 410, the plurality of the first sub-touch-control electrodes 411 are connected by the plurality of the first connection parts 412, for the same second touch-control electrode 420, the plurality of the second sub-touch-control electrodes 421 are connected by the plurality of second connection parts 422, the plurality of first connection parts 412 and the plurality of second connection parts 422 are intersected and spaced apart from each other, the plurality of the first sub-touch-control electrodes 411, the plurality of the first connection parts 412 and the plurality of the second sub-touch-control electrodes 420 are disposed in a same layer, the plurality of the second connection parts 422 are located between the plurality of the first connection parts 412 and the isolation structure 210, or the plurality of the second connection parts 422 are located at a side, away from the isolation structure 210, of the plurality of the first connection parts 412. The touch-control electrode layer 400 in this design has a high light transmittance, the alignment accuracy between the grid hole and the isolation opening 201 is high, the alignment accuracy between the grid hole and the light transmitting opening 202 is high, thereby light transmittance of the first area 13 may be improved. For example, a first conductive material layer may be deposited and patterned to form a plurality of first touch-control electrodes 410 and a plurality of the second sub-touch-control electrodes 421 in the plurality of the second sub-touch-control electrodes 420, and the first conductive material layer is patterned to be a plurality of grid holes; a layer of insulation layer 430 is deposited to cover the plurality of first touch electrodes 410 and the plurality of the second sub-touch-control electrodes 421 in the plurality of the second sub-touch-control electrodes 420; the insulation layer 430 is patterned to expose a plurality of through holes of the plurality of the second sub-touch-control electrodes 421; and a second conductive material layer may be deposited on the insulation layer 430 and patterned to form the plurality of the second connection parts 422 in the plurality of second touch-control electrodes 420, and each second connection part 422 of the plurality of second connection parts 422 is connected to each second sub-touch-control electrode 421 of the plurality of the second sub-touch-control electrodes 421 through each through hole of the plurality of through holes. The body part of the plurality of first touch-control electrodes 410 and the body part of the plurality of the second touch-control electrodes 420 are designed in a same layer in order to not consider the alignment problem between the grid holes of the plurality of first touch-control electrodes 410 and the grid holes of the first touch-control electrodes 410 and the second touch-control electrodes 420, this is beneficial for improving light transmittance of the touch-control electrode layer 400.

In at least one embodiment of the present disclosure, referring to FIG. 2 to FIG. 4 again, a width of the touch-control electrode block 401 of the grid pattern needs to be designed less than a gap between the plurality of the light emitting units 220, that is, an orthographic projection, located on the substrate 100, of the touch-control electrode block 401 of the grid pattern is located within an orthographic projection, located on the substrate 100, of the isolation structure 210, so that both of the orthographic projection, located on the substrate 100, of the isolation opening 201 and the orthographic projection, located on the substrate, of the light transmitting opening 202 are located within the orthographic projection, located on the substrate 100, of the corresponding grid hole. This design may allow the light emitted from the display panel to have a larger angle of incidence, thereby giving the display panel a wider viewing angle.

In at least one embodiment of the present disclosure, referring to FIG. 2 to FIG. 4 again, distances between the plurality of touch-control electrode blocks of the grid pattern between the adjacent two isolation openings 201 and the isolation opening 201 are equal, as for the adjacent two isolation openings 201 and the touch-control electrode block of the grid pattern between the adjacent two isolation openings 201, a minimum distance between an orthographic projection, located on the substrate, of any position of the touch-control electrode block and an orthographic projection, located on the substrate, of each of the adjacent two isolation openings 201 on the substrate is equal; and/or a distance between the plurality of touch-control electrode blocks of the grid pattern between the isolation opening 201 and the adjacent light transmitting opening 202 and isolation opening 201 is equal to a distance between the plurality of touch-control electrode blocks of the grid pattern between the isolation opening 201 and the adjacent light transmitting opening 202 and the light transmitting opening 202, as for the isolation opening 201 and the adjacent light transmitting opening 202, and the touch-control electrode block of the grid pattern between the isolation opening 201 and the adjacent light transmitting opening 202, a minimum distance between an orthographic projection, located on the substrate, of any one position of the touch-control electrode block and an orthographic projection, located on the substrate, of the isolation opening 201 is equal to a minimum distance between an orthographic projection, located on the substrate, of the position of the touch-control electrode block and an orthographic projection, located on the substrate, of the light transmitting opening 202. This design may make the maximum viewing angle of the light emitting units roughly equal in different directions, thereby alleviating color shift issues.

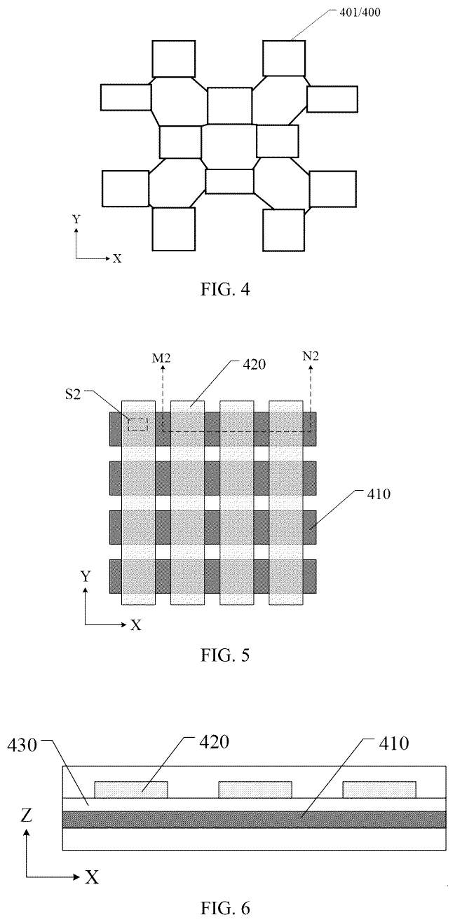

For example, in some embodiments of the present disclosure, the touch-control electrode block 401 of the grid pattern may be designed as a linear structure as shown in FIG. 2 and FIG. 4, the linear structure is composed of a straight line segment and a curved segment that are connected to each other, and a width of each part of the straight line segment and a width of each part of the curved segment are equal. For example, “distances between the plurality of touch-control electrode blocks and the two isolation openings 201 are equal” may be interpreted as the minimum distances between any one position of the plurality of the touch-control electrode blocks and the adjacent isolation opening 201 are equal, that is, the touch-control electrode block is located on a central dividing line of the adjacent isolation openings 201.

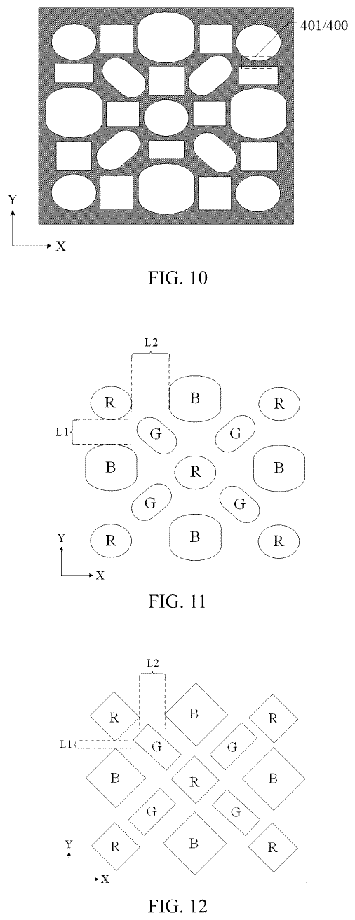

For example, in some other embodiments of the present disclosure, as shown in FIG. 9 and FIG. 10, the grid hole surrounded by the touch-control electrode block 401 of the grid pattern and the corresponding isolation opening and/or the corresponding light transmitting opening are conformal, so that minimum distances between orthographic projections, located on the substrate, of different positions of the touch-control electrode blocks 401 for surrounding a same grid hole and the orthographic projection, located on the substrate, of the isolation opening or the light transmitting opening are equal. Under the circumstance, a shape of the touch-control electrode blocks 401 is shown in FIG. 10. Under the circumstance, in order to ensure the viewing angle of the display panel, a first spacing may be formed between an edge of the grid hole and an edge of the corresponding isolation opening, and the first spacing may be set to a preset value, so that the maximum viewing angle of the light emitting units in different directions may be approximately equal.

In the embodiment of the present disclosure, a shape of the isolation opening (equivalent to a shape of the pixel) may be designed to increase a gap between the isolation openings under a condition that the light emitting area of the pixel (effective light emitting area of the light emitting units) and the pixel density PPI are not reduced, so as to enable larger area of the light transmitting openings, and details are specifically as follows.

In at least one embodiment of the present disclosure, referring to FIG. 2 to FIG. 3, FIG. 9 and FIG. 11 again, at least two opposite ends of the isolation opening 201 are arc-shaped. Under a condition that an area of the isolation opening 201 is not changed (a light emitting area of the light emitting unit is not changed) and a pixel density of the display panel is not changed, there is a relatively large gap between the adjacent isolation openings 201, so as to design the light transmitting opening 202 with a relatively large area to further improve the light transmittance of the first area 13. As for a principle that the design may increase a size of the light transmitting opening may refer to related descriptions in the forgoing embodiments shown in FIG. 11 and FIG. 12, and details are not described herein again.

In at least one embodiment of the present disclosure, referring to FIG. 2 and FIG. 9 the plurality of isolation openings 201 are classified into a first type opening 220a, a second type opening 220b and a third opening 220c, the light emitting unit R, the light emitting unit B and the light emitting unit B for emitting light with different colors are defined by the first type opening 220a, the second type opening 220b and the third opening 220c respectively, a wavelength of emergent light from a light emitting unit defined by the first type opening 220a, a wavelength of emergent light from a light emitting unit defined by the second type opening 220b and a wavelength of emergent light from a light emitting unit defined by the third opening 220c are decreased sequentially, such as the light emitting unit R, the light emitting unit G and the light emitting unit B emit red light, green light and blue light respectively. The plurality of isolation openings 201 are arranged in a plurality of rows and a plurality of columns, the first type opening 220a and the third type opening 220c are disposed in a same row of the plurality of rows and in a same column of the plurality of columns, both in a row and in a column where the first type opening 220a is located, the first type opening 220a and the third type opening 220c are disposed alternately, and the row where the first type opening 220a is located and the row where the second type opening is 220b located are disposed alternately, and the column where the first type opening 220a is located and the column where the second type opening 220b is located are disposed alternately.

In at least one embodiment of the present disclosure, a contour of the first type opening 220a is in a shape of circular, each of a contour of the second type opening 220b and a contour of the third type opening 220c includes two parallel edges and two semi-arc edges, the second type opening 220b has a first symmetry axis passing through the two semi-arc edges, and the third type opening 220c has a second symmetry axis passing through two the semi-arc edges, the second symmetry axis is parallel to an extension direction of the column where the third type opening 220c is located, the first symmetry axis is intersected with both of an extension direction of the row and an extension direction of the column, the first symmetry axis of the second type opening 220b passes through centroids of the two adjacent first type openings 220a located in adjacent columns, and as for the second type opening 220b in the same column, the adjacent second type openings 220b are axisymmetric, and a direction of symmetry axis is parallel to the extension direction of the row.

In the embodiments of the present disclosure, the shape of the light transmitting opening is not limited, and may be designed according to the requirements of the actual process, and the following describes several shapes of the light transmitting opening.

For example, in some embodiments of the present disclosure, the light transmitting opening is in a shape of circular. The diffraction at the light transmitting opening may be reduced with this design, so as to improve the optical effect of the first area.

For example, in some other embodiments of the present disclosure, the light transmitting opening 202 is in a shape of rectangular as shown in FIG. 2 and FIG. 9.

For example, in some more other embodiments of the present disclosure, a shape of an edge of the light transmitting opening 202 and a shape of an edge of the adjacent isolation opening 201 are conformal. The design area of the light transmitting opening may be increased, so as to further improve the light transmittance of the first area.

The principle that the design area of the light transmitting opening is increased by the shape design of the isolation opening is described by comparing the two embodiments shown in FIG. 11 and FIG. 12, the pixel arrangement modes in the two drawings are the same, the pixel density PPI in the two drawings is equal, the pixel area of emergent light with a same color (the effective light emitting area of the light emitting unit) in the two drawings is equal, but the shapes of the pixel (the shape of the isolation opening) are different, and details are specially as follows.

As shown in FIG. 11, the light emitting unit R is in a shape of circular, the diameter of the light emitting unit R is 26.6 μm, the light emitting unit G is in a shape of a runway type with two parallel sides and two semi-circular arc edges, the size of a rectangular determined by the two parallel edges is 8.6 μm (width)*17.8 μm (length), the total area of the light emitting unit G is 375.7 μm², the light emitting unit B is in a shape of a runway type with two parallel sides and two semi-circular arc edges, the size of a rectangular determined by the two parallel edges is 14.2 μm (width)*33.5 μm (length), the total area of the light emitting unit B is 1008 μm², a pitch of the pixel is 55.2 μm, since the PPI of the pixel is 460, a ratio of effective light emitting area of the light emitting unit R, effective light emitting area of the light emitting unit G, and effective light emitting area of the light emitting unit B is 1:1.3:1.9, and a minimum width of the isolation structure is 12 μm. In this case, a width of L1 is approximately 20 μm, and a width of L2 is approximately 25.2 μm.

As shown in FIG. 12, the light emitting unit R is in a shape of square, a length of a side of the square is 26.4 μm, the light emitting unit G is in a shape of rectangular, a width of the rectangular is 17.76 μm, a length of the rectangular is 25.67 μm, the light emitting unit B is in a shape of square, a length of a side of the square is 36.3 μm, a pitch of the pixel is 55.2 μm, since the PPI of the pixel is 460, a ratio of effective light emitting area of the light emitting unit R, effective light emitting area of the light emitting unit G, and effective light emitting area of the light emitting unit B is 1:1.3:1.9, and a minimum width of the isolation structure is 12 μm. In this case, a width of L1 is approximately 9.6 μm, and a width of L2 is approximately 13.5 μm.

It should be noted that the design area of the first region is not limited in the embodiments of the present disclosure, and the design may be tailored according to the actual process requirements and application scenarios of the display panel.

For example, in some embodiments of the present disclosure, all of the display area may be designed as the first area 13, that is, the light transmitting openings may be arranged in the entire display area of the display panel. In this design, the display panel may be applied in some scenarios such as transparent display.

For example, in some other embodiments of the present disclosure, referring to FIG. 1 again, the display area further includes a second area (an area, except for the display area 11, of the first area 13), and the second area is located on at least one side of the first area 13, and the light transmitting opening for transmitting light is only disposed in the first area 13. In this design, the display panel may be used in some scenarios such as fingerprint recognition or under-screen camera.

In at least one embodiment of the present disclosure, referring to FIG. 3 again, the display panel may further include a first encapsulation layer 310, and the first encapsulation layer 310 at least covers the light emitting unit 220 to protect the film layer of the light emitting unit 220 during the manufacturing process of the display panel. As for the first encapsulation layer 310 located between the isolation structure 210 and the touch-control electrode layer 400, the first encapsulation layer 310 includes a plurality of encapsulation units 311 corresponding to the isolation opening 201 respectively, and each encapsulation unit 311 of the plurality of encapsulation units covers the corresponding isolation opening 201. It should be noted that the light emitting units 220 for emitting light with different colors are independently manufactured, but each film layer (the evaporation film layer, such as the light emitting functional layer 223) in each light emitting unit 220 is deposited via a full-surface evaporation process on the display panel. For example, the plurality of light emitting units 220 are classified into a light emitting unit for emitting red light (R), a light emitting unit for emitting green light (G) and a light emitting unit for emitting blue light (B) respectively, and in the manufacturing process, the light emitting unit R, the light emitting unit G and the light emitting unit B are sequentially prepared, when the light emitting unit R is prepared, each light emitting unit R is formed in each of the first openings, the first encapsulation layer 310 is prepared on the display panel to cover the light emitting unit G, and then, the first encapsulation layer 310, the cathode of the light emitting unit R and the light emitting functional layer 223 are removed in some of the first openings (the final product is used to form the light emitting unit G and the light emitting unit B), a plurality of encapsulation unit 311 is formed by the remaining part of the first encapsulation layer 310, in this process, the first encapsulation layer 310 is configured to protect the light emitting unit R in the other first openings, the light emitting units G and the light emitting units B are sequentially prepared based on the method, and the first encapsulation layer 310 as shown in FIG. 3 is formed. It should be noted that encapsulation unit 311 is prepared every time in the process of preparing the light emitting units with different colors, so that the final first encapsulation layer 310 is composed of a plurality of encapsulation units 311; and in addition, in above manufacturing process, the first encapsulation layer 310 in the light transmitting opening 202 may be removed to further increase the light transmittance of the first area.

In at least one embodiment of the present disclosure, referring to FIG. 3 again, at least based on a consideration of improving the encapsulation effect, the encapsulation unit 311 may extend to a side, away from the substrate 100, of the crown portion 212, and the principle may refer to related descriptions in the embodiments shown in FIG. 14A to FIG. 14F. In this case, at least one portion where the encapsulation unit 311 overlaps with the crown portion 212 may form a suspended portion to be spaced apart from the crown portion 212.

In at least one embodiment of the present disclosure, referring to FIG. 3 again, the display panel may also include a second encapsulation layer 320 and a third encapsulation layer 330 that cover the first encapsulation layer 310, the encapsulation layer 300 is composed of the first encapsulation layer 310, the second encapsulation layer 320 and the third encapsulation layer 330, the second encapsulation layer 320 is located between the first encapsulation layer 310 and the third encapsulation layer 330, the first encapsulation layer 310 and the third encapsulation layer 330 are inorganic layers, and the inorganic layer has high density to isolate water and oxygen, and the second encapsulation layer 320 is an organic layer, such that the organic layer has a relatively large thickness to flatten the surface of the display panel.

In at least one embodiment of the present disclosure, referring to FIG. 3 again, the substrate 100 may include a base and a driving circuit layer located on the base, the driving circuit layer includes a plurality of pixel driving circuits located in the display area, and the display functional layer is located on the driving circuit layer. For example, the pixel driving circuit may include a plurality of transistors TFT and capacitors, like formed as 2T1C (that is two transistors (TFT) and a capacitor), 3T1C or 7T1C. The pixel driving circuit is connected to the light emitting unit 200 to control the on-off state of the light emitting unit 220 and the brightness of the light emitting unit 220.

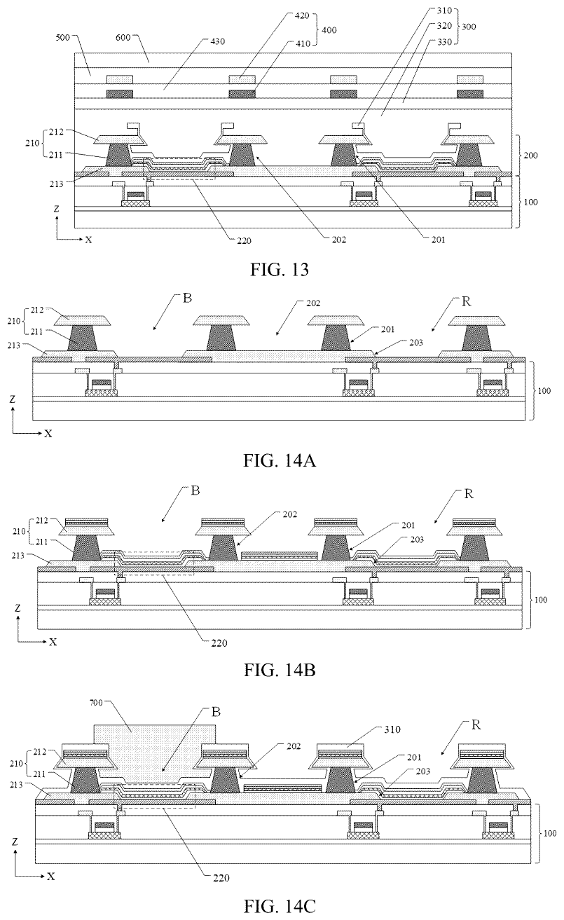

For example, as shown in FIG. 13, the display panel may further include structures such as an optical film 500 and a cover plate 600.

The following describes a manufacturing process of the display panel shown in FIG. 3 with reference to FIG. 14A to FIG. 14F, so as to intuitively demonstrate the principle that the isolation structure may increase the pixel arrangement density PPI.

As shown in FIG. 14A, providing a substrate 100 and forming a plurality of anodes 221 arranged in an array on the substrate 100; depositing an insulating material film layer (such as an inorganic material film layer) on the substrate 100 on which the anode is formed; forming a support portion 211 and a crown portion 212 on the display panel, and forming a plurality of isolation openings 201 and a plurality of light transmitting openings 202; performing a patterning process on the insulating material film layer to form the pixel-defining layer 213 (the planar shape is grid-shaped), the pixel-defining layer 213 includes a plurality of pixel openings 203 and covers a gap between the adjacent anodes, in this way, the planar shape of the pixel-defining layer 213 is grid-shaped.

In an embodiment of the present disclosure, the patterning process may be a photoetching patterning process, for example, the process may include: coating a photoresist on a structure layer that needs to be patterned, exposing the photoresist using a mask plate, developing the exposed photoresist to get a photoresist pattern, etching the structure layer using the photoresist pattern (optionally wet etch or dry etch), and then optionally removing the photoresist pattern. It should be noted that, in a case that the material of the structure layer (for example, the photoresist pattern 700 below) includes the photoresist, the structure layer may be directly exposed with the mask plate to form a desired pattern.

It should be noted that after the isolation structure 210 with the plurality of isolation openings 201 and the plurality of light transmitting openings 202 is formed, the patterning process is performed on the insulating material film layer to form the pixel-defining layer 213 with the pixel opening 203, such that, in the process for forming the isolation structure 210, a damage to the anode (for example corrosion) may be prevented, and in this case, the insulating material film layer may protect the anode.

As shown in FIG. 14B, evaporating a light emitting functional layer and a cathode that are on the substrate 100 to form a light emitting unit 220 in each isolation opening 201 of the isolation structure 210, since the evaporation in this process does not use a mask plate, the material for evaporating may also be deposited on the crown portion 212 and in the plurality of light transmitting openings 202. For example, light emitting layer functional layer in light emitting unit 220 that is evaporated may emit blue light (B), that is, in this stage, light emitting unit 220 for emitting blue light is formed in each first opening 201 of the isolation structure 210 and each second opening 202 of the isolation structure 210.

As shown in FIG. 14C, forming a first encapsulation layer 310 by deposition to cover the light emitting unit 200, and the first encapsulation layer 310 covers the entire display area at this stage; and forming (such as coated) a photoresist on the first encapsulation layer 310, and performing the patterning process on the photoresist to form the photoresist pattern 700, and the photoresist pattern 700 covers only at least one part of the isolation structure 210 of the plurality of isolation openings 201 (the isolation opening 201 where the light emitting unit B of the finished display panel is located).

As shown in FIG. 14D, etching the surface of the display panel by taking the photoresist pattern 700 as a mask plate, removing the first encapsulation layer 310, the cathode, and the light emitting functional layer that are not covered by the photoresist pattern 700; and then removing the residual photoresist pattern 700.

As shown in FIG. 14E, the steps shown in FIG. 14A to FIG. 14D are repeated, so as to form the light emitting units 220 for emitting red light and the light emitting units 220 for emitting green light in the other isolation openings 201 respectively.

As shown in FIG. 14F, forming a second encapsulation layer 320 and a third encapsulation layer 330 respectively on the first encapsulation layer 310.

Referring to FIG. 3 again, preparing the touch-control electrode layer 400 on the third encapsulation layer 330, and the manufacturing process of the touch-control electrode layer 400 may refer to related descriptions in the foregoing embodiments, and details are not described herein again.

It should be noted that, in some embodiments of the present disclosure, some of the film layers, such as the light emitting layer in the light emitting functional layer may be prepared in a non-evaporation method, for example an inkjet printing, the specific preparation method may be selected according to the materials of the film layers, for example, when the film layers are polymer materials, and the polymer materials are not suitable for evaporation, and these film layers may be prepared by the inkjet printing method.

At least one embodiment of the present disclosure further provides a pixel arrangement structure, the pixel arrangement structure includes a plurality of first sub-pixels, a plurality of second sub-pixels, and a plurality of third sub-pixels, a wavelength of emergent light of the plurality of first sub-pixels, a wavelength of emergent light of the plurality of second sub-pixels and a wavelength of emergent light of the plurality of third sub-pixels are decreased sequentially, the plurality of first sub-pixels, the plurality of second sub-pixels and the plurality of third sub-pixels are arranged in a plurality of rows and a plurality of columns, the first sub-pixel and the third sub-pixel are disposed in a same row of the plurality of rows and in a same column of the plurality of columns, both in a row and in a column where the first sub-pixel is located, the first sub-pixel and the third sub-pixel are disposed alternately, the row where the first sub-pixel and the third sub-pixel are located and the row where the second sub-pixel is located, the column where the first sub-pixel and the third sub-pixel are located and the column where the second sub-pixel is located, and two opposite ends of at least one of the first sub-pixels, the second sub-pixels and the third sub-pixels are arc-shaped. The arrangement mode of the sub-pixels in the pixel arrangement structure in the design may refer to related descriptions in the embodiments shown in FIG. 2, FIG. 9, and FIG. 11, the first sub-pixel, the second sub-pixel, and the third sub-pixel may correspond to the light emitting unit R defined in the first-type opening, the light emitting unit G defined in the second-type opening, and the light emitting unit B defined in the third type opening respectively, for example, the light emitting unit R is an physical light emitting structure of the first sub-pixel, the light emitting unit G is an physical light emitting structure of the second sub-pixel, and the light emitting unit B is an physical light emitting structure of the third sub-pixel.

At least one embodiment of the present disclosure, a contour of the first sub-pixel is in a shape of circular, each of a contour of the second sub-pixel and a contour of the third sub-pixel comprises two parallel edges and two semi-arc edges, the first sub-pixel has a first symmetry axis passing through the two semi-arc edges, and the second sub-pixel has a second symmetry axis passing through two the semi-arc edges, the first symmetry axis is parallel to an extension direction of the column where the first sub-pixel is located, the second symmetry axis is intersected with both of an extension direction of the row and an extension direction of the column, the second symmetry axis of the second sub-pixel passes through centroids of the two adjacent third sub-pixel located in adjacent columns, and as for the second sub-pixel in the same column, the adjacent the second sub-pixel are axisymmetric, and a direction of symmetry axis is parallel to the extension direction of the row. The design methods of the first sub-pixel, the second sub-pixel, and the third sub-pixel in the design may refer to related descriptions of the first type opening, the second type opening, and the third type opening in the embodiments shown in FIG. 9 and FIG. 11, and details are not described herein again.

At least one embodiment of the present disclosure provides a display panel, and the display panel includes an isolation structure, a plurality of isolation openings and a plurality of light transmitting openings are formed surrounded by the isolation structure, each isolation opening of the plurality of isolation openings is provided to accommodate a light emitting unit, and the isolation opening and the light transmitting opening are disposed at intervals, the plurality of isolation openings are classified into a first type opening, a second type opening and a third opening, a wavelength of emergent light from a light emitting unit defined by the first type opening, a wavelength of emergent light from a light emitting unit defined by the second type opening and a wavelength of emergent light from a light emitting unit defined by the third opening are decreased sequentially, the plurality of isolation openings are arranged in a plurality of rows and a plurality of columns, the first type opening and the third type opening are disposed in a same row of the plurality of rows and in a same column of the plurality of columns, both in a row and in a column where the first type opening is located, the first type opening and the third type opening are disposed alternately, the row where the first type opening is located and the row where the second type opening is located are disposed alternately, and the column where the first type opening is located and the column where the second type opening is located are disposed alternately, and edges of two opposite ends of at least one of the first type opening, the second type opening, and the third type opening are arc-shaped. The light emitting units defined in the first-type opening, the second type opening, and the third type opening correspond to the first sub-pixel, the second sub-pixel, and the third sub-pixel mentioned in the foregoing embodiment. In this design, the design area of the light transmitting opening may be increased without changing the light emitting area of each light emitting unit and the pixel density (PPI) of the display panel, and the specific principle may refer to the related description in the foregoing embodiments, and details are not described herein again.

At least one embodiment of the present disclosure provides a display panel, a contour of the first type opening is in a shape of circular, each of a contour of the second type opening and a contour of the third type opening includes two parallel edges and two semi-arc edges, the second type opening has a first symmetry axis passing through the two semi-arc edges, and the third type opening has a second symmetry axis passing through the two semi-arc edges, the second symmetry axis is parallel to an extension direction of the column where the third type opening is located, the first symmetry axis is intersected with both of an extension direction of the row and an extension direction of the column, the first symmetry axis of the second type of opening passes through centroids of the two adjacent first type openings located in adjacent columns, and as for the second type opening in the same column, the adjacent second type openings are axisymmetric, and a direction of a symmetry axis is parallel to the extension direction of the row.

At least one embodiment of the present disclosure provides a display device, including the display panel in the foregoing embodiments. In addition, when the first region is the recognition region, the display device may include a recognition device, and an orthographic projection, located on the substrate, of the recognition device at least partially overlaps with the first area.

For example, in some embodiments of the present disclosure, the recognition device includes at least one fingerprint identification sensor. For example, the fingerprint recognition sensor may be disposed at a side, away from the display functional layer, of the substrate, or the fingerprint recognition sensor may be disposed in the substrate.

For example, in some other embodiments of the present disclosure, the recognition device may be a camera, and the camera is located at a side, away from the display functional layer, of the substrate.

For example, in the embodiments of the present disclosure, the display device may be any product or component with display function, such as a television, a digital camera, a mobile phone, a watch, a tablet computer, a notebook computer or a navigator.

What is claimed is:

1. A display panel, comprising:
a substrate;
an isolation structure, located on the substrate, wherein a plurality of isolation openings and a plurality of light transmitting openings are formed surrounded by the isolation structure, each isolation opening of the plurality of isolation openings is provided to accommodate a light emitting unit, and the isolation opening and the light transmitting opening are disposed at intervals; and
a touch-control electrode layer, located at a side, away from the substrate, of the isolation structure, wherein the touch-control electrode layer comprises a plurality of touch-control electrode blocks, adjacent touch-control electrode blocks of the plurality of touch-control electrode blocks are connected sequentially to form a grid pattern with a plurality of grid holes, each of an orthographic projection, located on the substrate, of the isolation opening and an orthographic projection, located on the substrate, of each light transmitting opening of the plurality of light transmitting openings at least partially overlaps with an orthographic projection, located on the substrate, of grid hole of the plurality of grid holes of the grid pattern.

2. The display panel according to claim 1, wherein the light emitting unit comprises an anode, a light emitting functional layer and a cathode which are stacked sequentially on the substrate, the light emitting functional layer and the cathode are located in the isolation opening,
the isolation structure comprises a support portion and a crown portion, the crown portion is located at a side, away from the substrate, of the support portion, an orthographic projection, located on the substrate, of an end, towards the crown portion, of the support portion is located within an orthographic projection, located on the substrate, of the crown portion, and
the support portion is a conductive structure, and the cathode is connected to the support portion.

3. The display panel according to claim 2, wherein the support portion comprises at least two sub-support portions, and an orthographic projection, located on the substrate, of the sub-support portion which is far away from the substrate is located within an orthographic projection, located on the substrate, of the sub-support portion which is close to the substrate.

4. The display panel according to claim 2, wherein the display panel further comprises a pixel-defining layer, the pixel-defining layer is located between the isolation structure and the substrate, the pixel-defining layer defines a plurality of pixel openings corresponding to the isolation opening respectively, each pixel opening of the plurality of pixel openings is in communication with the corresponding isolation opening, an orthographic projection, located on the substrate, of the pixel opening is located within an orthographic projection, located on the substrate, of the corresponding isolation opening, and an edge of the anode and a gap between the adjacent anodes are covered by the pixel-defining layer, so that the anode is exposed by the pixel opening.

5. The display panel according to claim 4, wherein the pixel-defining layer is an inorganic material film layer.

6. The display panel according to claim 4, further comprising a first encapsulation layer located between the isolation structure and the touch-control electrode layer,
wherein the first encapsulation layer comprises a plurality of encapsulation units corresponding to the isolation structure respectively, and each encapsulation unit of the plurality of encapsulation units covers the corresponding isolation opening.

7. The display panel according to claim 1, wherein the touch-control electrode layer comprises a plurality of first touch-control electrodes arranged in multiple rows and a plurality of second touch-control electrodes arranged in multiple columns, each first touch-control electrode of the plurality of first touch-control electrodes is composed of a plurality of the touch-control electrode blocks interconnected in a row direction, and each second touch-control electrode of the plurality of second touch-control electrodes is composed of a plurality of the touch-control electrode blocks interconnected in a column direction, and
the first touch-control electrode and the second touch-control electrode are spaced apart from each other and intersected with each other, and the grid pattern is formed by the first touch-control electrode and the second touch-control electrode.

8. The display panel according to claim 7, wherein the first touch-control electrode is located between the second touch-control electrode and the isolation structure.

9. The display panel according to claim 8, wherein the first touch-control electrode comprises a plurality of first sub-touch-control electrodes spaced apart from each other and a plurality of first connection parts, the second touch-control electrode comprises a plurality of second sub-touch-control electrodes spaced apart from each other and a plurality of second connection parts,
for the same first touch-control electrode, the plurality of the first sub-touch-control electrodes are connected by the plurality of first connection parts,
for the same second touch-control electrode, the plurality of the second sub-touch-control electrodes are connected by the plurality of second connection parts,
the first touch-control electrode and the second touch-control electrode are intersected with each other through the plurality of first connection parts and the plurality of second connection parts,
the plurality of the first sub-touch-control electrodes, the plurality of first connection parts and the plurality of the second sub-touch-control electrodes are disposed in a same layer, the plurality of first connection parts and the plurality of second connection parts are spaced apart from each other, and
the plurality of the second sub-touch-control electrodes are located between the plurality of the first sub-touch-control electrodes and the isolation structure, or the plurality of the second sub-touch-control electrodes are located at a side, away from the isolation structure, of the plurality of the first sub-touch-control electrodes.

10. The display panel according to claim 1, wherein an orthographic projection, located on the substrate, of the touch-control electrode block of the grid pattern is located within an orthographic projection, located on the substrate, of the isolation structure, so that both of the orthographic projection, located on the substrate, of the isolation opening and the orthographic projection, located on the substrate, of the light transmitting opening are located within the orthographic projection, located on the substrate, of the corresponding grid hole.

11. The display panel according to claim 10, wherein as for the adjacent two isolation openings and the touch-control electrode block of the grid pattern between the adjacent two isolation openings, a minimum distance between an orthographic projection, located on the substrate, of any position of the touch-control electrode block and an orthographic projection, located on the substrate, of each of the adjacent two isolation openings on the substrate is equal, and
as for the isolation opening and the adjacent light transmitting opening, and the touch-control electrode block of the grid pattern between the isolation opening and the adjacent light transmitting opening, a minimum distance between an orthographic projection, located on the substrate, of any position of the touch-control electrode block and an orthographic projection, located on the substrate, of the isolation opening is equal to a minimum distance between an orthographic projection, located on the substrate, of the position of the touch-control electrode block and an orthographic projection, located on the substrate, of the light transmitting opening.

12. The display panel according to claim 11, wherein the grid hole, corresponding to the isolation opening, surrounded by the touch-control electrode block of the grid pattern and the corresponding isolation opening are conformal, the grid hole, corresponding to the corresponding light transmitting opening, surrounded by the touch-control electrode block of the grid pattern and the corresponding light transmitting opening are conformal, so that minimum distances between orthographic projections, located on the substrate, of different positions of the touch-control electrode blocks for surrounding a same grid hole and the orthographic projection, located on the substrate, of the isolation opening or the light transmitting opening are equal.

13. The display panel according to claim 1, wherein at least two opposite ends of the isolation opening are arc-shaped.

14. The display panel according to claim 13, wherein the plurality of isolation openings are classified into a first type opening, a second type opening and a third opening, the light emitting units for emitting light with different colors are defined by the first type opening, the second type opening and the third opening respectively,
a wavelength of emergent light from a light emitting unit defined by the first type opening, a wavelength of emergent light from a light emitting unit defined by the second type opening and a wavelength of emergent light from a light emitting unit defined by the third opening are decreased sequentially,
the plurality of isolation openings are arranged in a plurality of rows and a plurality of columns, the first type opening and the third type opening are disposed in a same row of the plurality of rows and in a same column of the plurality of columns,
both in a row and in a column where the first type opening is located, the first type opening and the third type opening are disposed alternately, and
the row where the first type opening is located and the row where the second type opening is located are disposed alternately, and the column where the first type opening is located and the column where the second type opening is located are disposed alternately.

15. The display panel according to claim 14, wherein a contour of the first type opening is in a shape of circular, each of a contour of the second type opening and a contour of the third type opening comprises two parallel edges and two semi-arc edges,
the second type opening has a first symmetry axis passing through the two semi-arc edges, and the third type opening has a second symmetry axis passing through the two semi-arc edges,
the second symmetry axis is parallel to an extension direction of the column where the third type opening is located, the first symmetry axis is intersected with both of an extension direction of the row and an extension direction of the column, the first symmetry axis of the second type of opening passes through centroids of the two adjacent first type openings located in adjacent columns, and
as for the second type opening in the same column, the adjacent second type openings are axisymmetric, and a direction of symmetry axis is parallel to the extension direction of the row.

16. The display panel according to claim 1, wherein
the light transmitting opening is in a shape of circular; or
the light transmitting opening is in a shape of rectangular; or
a shape of an edge of the light transmitting opening and a shape of an edge of the adjacent isolation opening are conformal.

17. The display panel according to claim 1, wherein the display panel comprises a display area, the display area comprises a first area and a second area, the second area is located on at least one side of the first area, and the light transmitting opening is located in the first area.

18. A display panel, comprising an isolation structure, wherein a plurality of isolation openings and a plurality of light transmitting openings are formed surrounded by the isolation structure, each isolation opening of the plurality of isolation openings is provided to accommodate a light emitting unit, and the isolation opening and the light transmitting opening are disposed at intervals,
the plurality of isolation openings are classified into a first type opening, a second type opening and a third opening, a wavelength of emergent light from a light emitting unit defined by the first type opening, a wavelength of emergent light from a light emitting unit defined by the second type opening and a wavelength of emergent light from a light emitting unit defined by the third opening are decreased sequentially,
the plurality of isolation openings are arranged in a plurality of rows and a plurality of columns, the first type opening and the third type opening are disposed in a same row of the plurality of rows and in a same column of the plurality of columns, both in a row and in a column where the first type opening is located, the first type opening and the third type opening are disposed alternately, the row where the first type opening is located and the row where the second type opening is located are disposed alternately, and the column where the first type opening is located and the column where the second type opening is located are disposed alternately, and
edges of two opposite ends of at least one of the first type opening, the second type opening, and the third type opening is arc-shaped.

19. The display panel according to claim 18, wherein a contour of the first type opening is in a shape of circular, each of a contour of the second type opening and a contour of the third type opening comprises two parallel edges and two semi-arc edges,
the second type opening has a first symmetry axis passing through the two the semi-arc edges, and the third type opening has a second symmetry axis passing through the two semi-arc edges,
the second symmetry axis is parallel to an extension direction of the column where the third type opening is located, the first symmetry axis is intersected with both of an extension direction of the row and an extension direction of the column, the first symmetry axis of the second type of opening passes through centroids of the two adjacent first type openings located in adjacent columns, and
as for the second type opening in the same column, the adjacent second type openings are axisymmetric, and a direction of a symmetry axis is parallel to the extension direction of the row.

20. A display device, comprising a display panel according to claim 1.
